(19) United States
(12) Patent Application Publication
(10) Pub. No.: US 2025/0379175 A1
(43) Pub. Date: Dec. 11, 2025

(54) SEMICONDUCTOR DEVICE AND MANUFACTURING METHOD THEREOF

(71) Applicant: Innolux Corporation, Miaoli County (TW)

(72) Inventors: Kai-Hsiang Tu, Miaoli County (TW); You-Ruey Shen, Miaoli County (TW); Te-Hsun Lin, Miaoli County (TW); Wen-Hsiang Liao, Miaoli County (TW); Ker-Yih Kao, Miaoli County (TW)

(73) Assignee: Innolux Corporation, Miaoli County (TW)

(21) Appl. No.: 19/212,707

(22) Filed: May 20, 2025

Related U.S. Application Data
(60) Provisional application No. 63/658,448, filed on Jun. 11, 2024.

(30) Foreign Application Priority Data
Nov. 13, 2024 (CN) 202411619915.0

(51) Int. Cl. H01L 23/00; H01L 21/48; H01L 21/56; H01L 23/31; H01L 23/373; H01L 23/498; H01L 25/11

(52) U.S. Cl. CPC H01L 24/32; H01L 21/4846; H01L 21/4871; H01L 21/565; H01L 23/3185; H01L 23/3736; H01L 23/49816; H01L 24/29; H01L 25/112; H01L 2224/2919; H01L 2224/32059; H01L 2224/32258; H01L 2924/3512

(57) ABSTRACT

A semiconductor device and a manufacturing method thereof are provided. The semiconductor device includes an electronic unit, an encapsulation layer, a circuit structure, a protective layer, a first heat conducting element, and a second heat conducting element. The encapsulation layer surrounds the electronic unit and has a first side and a second side opposite to each other. The circuit structure is disposed on the first side of the encapsulation layer and electronically connected to the electronic unit. The protective layer is disposed on the second side of the encapsulation layer. The first heat conducting element is disposed on the protective layer. The second heat conducting element is disposed on the first heat conducting element. A thermal conductivity of the second heat conducting element is different from a thermal conductivity of the first heat conducting element.

### CROSS-REFERENCE TO RELATED APPLICATION

This application claims the priority benefit of U.S. provisional application Ser. No. 63/658,448, filed on Jun. 11, 2024 and China application serial no. 202411619915.0, filed on Nov. 13, 2024. The entirety of each of the above-mentioned patent applications is hereby incorporated by reference herein and made a part of this specification.

### BACKGROUND

### Technical Field

The disclosure relates to a semiconductor device and a manufacturing method thereof, and more particularly, to a semiconductor device with better structural reliability and a manufacturing method thereof.

### Description of Related Art

In a wafer-level package (WLP) process or a panel-level package (PLP) process, a surface processing method is required be used to thin an electronic unit or a package structure, or to perform surface roughness to improve an adhesion force between film layers. Therefore, a design of the surface processing method and optimization of a manufacturing process may improve structural reliability of an electronic device or a semiconductor device.

### SUMMARY

The disclosure is directed to a semiconductor device having better structural reliability.

The disclosure is further directed to a manufacturing method of a semiconductor device, which is used to manufacture the above semiconductor device.

According to an embodiment of the disclosure, a semiconductor device includes an electronic unit, an encapsulation layer, a circuit structure, a protective layer, a first heat conducting element, and a second heat conducting element. The encapsulation layer surrounds the electronic unit, and has a first side and a second side opposite to each other. The circuit structure is disposed on the first side of the encapsulation layer, and is electrically connected to the electronic unit. The protective layer is disposed on the second side of the encapsulation layer. The first heat conducting element is disposed on the protective layer. The second heat conducting element is disposed on the first heat conducting element. A thermal conductivity of the second heat conducting element is different from a thermal conductivity of the first heat conducting element.

According to an embodiment of the disclosure, a manufacturing method of a semiconductor device includes the following steps. An encapsulation layer is formed on an electronic unit. The encapsulation layer surrounds the electronic unit. The encapsulation layer is ground until a backside surface of the electronic unit is exposed. A circuit structure is formed on a first side of the encapsulation layer. The circuit structure is electrically connected to the electronic unit. A protective layer is formed on a second side of the encapsulation layer. A first heat conducting element is formed on the protective layer. A second heat conducting element is formed on the first heat conducting element. A thermal conductivity of the second heat conducting element is different from a thermal conductivity of the first heat conducting element.

Based on the above, in the embodiment of the disclosure, the protective layer is located on the second side of the encapsulation layer, and the first heat conducting element and the second heat conducting element having different thermal conductivities are sequentially disposed on the protective layer. The protective layer may improve and/or enhance the bursting strength of the electronic unit, and the heat conducting element may enable the semiconductor device in the disclosure to have the better heat dissipation effect.

In order for the aforementioned features and advantages of the disclosure to be more comprehensible, embodiments accompanied with drawings are described in detail below.

### BRIEF DESCRIPTION OF THE DRAWINGS

FIG. 1 is a schematic cross-sectional view of a semiconductor device according to an embodiment of the disclosure.

FIG. 2 is a schematic cross-sectional view of a semiconductor device according to another embodiment of the disclosure.

FIG. 3 is a schematic cross-sectional view of a semiconductor device according to another embodiment of the disclosure.

FIG. 4 is a schematic cross-sectional view of a semiconductor device according to another embodiment of the disclosure.

FIG. 5A to FIG. 5C are schematic partial cross-sectional enlarged views of multiple semiconductor devices according to multiple embodiments of the disclosure.

FIG. 6A is a schematic top view of a semiconductor device according to an embodiment of the disclosure.

FIG. 6B is a schematic partial cross-sectional view of the semiconductor device in FIG. 6A.

FIG. 7A to FIG. 7C are schematic cross-sectional views of a manufacturing method of a semiconductor device according to an embodiment of the disclosure.

FIG. 8 is a schematic cross-sectional view of a semiconductor device according to another embodiment of the disclosure.

### DETAILED DESCRIPTION OF DISCLOSED EMBODIMENTS

The disclosure can be understood by referring to the following detailed description in combination with the accompanying drawings. It should be noted that in order to make it easy for the reader to understand and for the simplicity of the drawings, the multiple drawings in this disclosure only depict a part of the electronic device, and the specific components in the drawings are not drawn according to actual scale. In addition, the number and size of each component in the drawings are only for exemplary purpose, and are not intended to limit the scope of the disclosure.

Throughout the disclosure and the appended claims, certain words are used to refer to specific components. Those skilled in the art should understand that electronic device manufacturers may refer to the same components by different names. The disclosure does not intend to distinguish those components with the same function but different names.

In the following description and claims, the terms “contain” and “include” are open-ended terms, so they should be interpreted as “include but not limited to . . . ”.

In addition, relative terms, such as “lower” or “bottom” and “upper” or “top”, may be used in the embodiments to describe a relative relationship between one element and another element of the drawings. It may be understood that if the device in the drawings is turned upside down, the elements described on the “lower” side shall become the elements on the “upper” side.

In some embodiments of the disclosure, terms such as “connect” and “interconnect” with respect to bonding and connection, unless specifically defined, may refer to two structures that are in direct contact (in indirect contact) with each other, or may refer to two structures that are indirectly in contact with each other, wherein there are other structures set between these two structures. In addition, the terms that describe joining and connecting may apply to the case where both structures are movable or both structures are fixed. In addition, the term “coupling” involves the transfer of energy between two structures by means of direct or indirect electrical connection, or the transfer of energy between two separate structures by means of mutual induction.

It should be understood that when an element or a film layer is described as being “on” or “connected to” another element or film layer, it may be directly on or connected to the another element or film layer, or there is an intervening element or film layer therebetween (an indirect situation). When an element is described as being “directly on” or “directly connected” to another element or film layer, there is no intervening element or film layer therebetween.

In some embodiments of the disclosure, “adjacent” may, for example, mean that two structures overlap each other in an extension direction of the electronic device or in an extension direction perpendicular to the electronic device. In some embodiments, there are no other components between the two structures. In some embodiments, it may also mean that there are other structures disposed between the two structures.

The terms “approximately”, “equal to”, “equal” or “same”, and “essentially” or “substantially” are generally interpreted as within 20% of a given value or range, or as within 10%, 5%, 3%, 2%, 1%, or 0.5% of the value or range.

In the present disclosure, optical microscopy (OM), scanning electron microscope (SEM), film thickness profiler (α-step), ellipsometer, or other suitable methods may be adopted to measure the area, width, thickness or height of various elements, or the distance or spacing between elements. In detail, according to some embodiments, an SEM may be used to obtain an image of cross-sectional structure including an elements to be measured, and measure the area, width, thickness or height of various elements, or distance or spacing between elements.

In some embodiments of the disclosure, a definition of roughness determination may be observed by SEM. On a concave-convex surface, it may be seen that peaks and valleys of a surface relief have a distance difference of 0.15 micrometers (μm) to 1 μm. Measurement of the roughness determination may include using SEM, a transmission electron microscope (TEM), etc. to observe the surface relief at the same appropriate magnification, and comparing a relief condition by taking a sample of a unit length (e.g., 10 μm), which is a roughness range thereof. Here, “appropriate magnification” means that roughness (Rz) or average roughness (Ra) of at least 10 undulating peaks may be seen on at least one surface under a field of view of this magnification.

In some other embodiments, the used term “roughness” refers to a degree of undulations on a surface of an object. Specifically, a value of “roughness” of a surface or a side wall may be obtained according to ten-point average roughness (Rz). The ten-point average roughness (Rz) is defined as taking five peak values and five valley values within an evaluation length, and calculating a sum of an absolute average value of the five peak values and an absolute average value of the five valley values. Specifically, the ten-point average roughness (Rz) is calculated according to the following formula.

$${R}_{z} = \frac{1}{5} {\sum }_{i = 1}^{5} {R}_{pi -} {R}_{vi}$$

Rₚᵢ and Rᵥᵢ are the i-th peak value and the i-th trough value respectively. In some embodiments, the term “roughness” used herein refers to average roughness, and the roughness may be measured using common instruments in the art to which the disclosure belongs. For example, the average roughness of the surface may be measured using a focus ion beam (FIB) microscope with a magnification of 5000 to 50,000 times, scanning electron microscopy (SEM), transmission electron microscopy (TEM), or atomic force microscopy (AFM) with a measurement scale of 10 μm to 100 μm.

In other embodiments, the Young's modulus may be measured by a tensile testing machine, a universal testing machine, a push-pull force machine (e.g., a machine model of 5565 from the manufacturer, INSTRON CORPORATION), or other suitable testing devices. In addition, in another embodiment, the Young's modulus may be measured based on ASTM D882 (a standard test method for tensile properties of plastic sheets) method established by ASTM (American Society for Testing and Materials) international standardization organization or other suitable test standards, but the disclosure is not limited thereto.

As the used herein, the terms “film” and/or “layer” may refer to any continuous or discontinuous structures and materials (e.g., materials deposited by the methods disclosed herein). For example, films and/or layers may include two-dimensional materials, three-dimensional materials, nanoparticles, or even partial or complete molecular layers, or partial or complete atomic layers, or clusters of atoms and/or molecules. The film or layer may include a material or layer having pinholes, which may be at least partially continuous.

Although the terms first, second, third . . . can be used to describe a variety of elements, the elements are not limited by this term. This term is only used to distinguish a single element from other elements in the specification. Different terminologies may be adopted in claims, and replaced with the first, second, third . . . in accordance with the order of elements specified in the claims. Therefore, in the following description, the first element may be described as the second element in the claims.

Unless otherwise defined, all terms (including technical and scientific terms) used herein have the same meaning as commonly understood by people skilled in the art to which the disclosure pertains. It is understood that these terms, such as those defined in commonly used dictionaries, should be interpreted as having meanings consistent with the relevant art and the background or context of the disclosure, and should not be interpreted in an idealized or overly formal manner unless otherwise defined in the embodiments of the disclosure.

In the disclosure, the features of multiple embodiments to be described below may be replaced, recombined, or mixed to form other embodiments without departing from the spirit of the disclosure.

The electronic device in the disclosure may include a power module, a semiconductor device, a semiconductor package device, a display device, an antenna device, a sensing device, a light emitting device, or a splicing device, but the disclosure is not limited thereto. The electronic device may include a bendable or flexible electronic device. The electronic device may include an electronic element. The electronic element may include a passive device, an active device, or a combination of the above, such as capacitors, resistors, inductors, variable capacitors, filters, diodes, transistors, sensors, MEMS devices, liquid crystal chips, etc., but the disclosure is not limited thereto. The diode may include a light emitting diode or a non-light emitting diode. The diode includes a P-N junction diode, a PIN diode, or a constant current diode. The light emitting diode may include, for example, an organic light emitting diode (OLED), a mini LED, a micro LED, a quantum dot LED, fluorescence, phosphor or other suitable materials, or a combination of the above, but the disclosure is not limited thereto. The sensor may include, for example, capacitive sensors, optical sensors, electromagnetic sensors, fingerprint sensors (FPS), touch sensors, antennas, or pen sensors, but the disclosure is not limited thereto. In the following, the display device will be used as an electronic device to describe the disclosure, but the disclosure is not limited thereto. According to the embodiments of the disclosure, a manufacturing method of the provided electronic device may be applied, for example, to a wafer-level package (WLP) process or a panel-level package (PLP) process, and a chip first process or a chip last/RDL first process may be adopted, which will be further described in detail below. The electronic device referred to in the disclosure may include a system on package (SoC), a system in package (SiP), an antenna in package (AiP), an co-packaged optics (CPO,) or a combination of the above, but the disclosure is not limited thereto.

Reference will now be made in detail to the exemplary embodiments of the disclosure, examples of which are illustrated in the accompanying drawings. Whenever possible, the same reference numerals are used to represent the same or similar parts in the accompanying drawings and description.

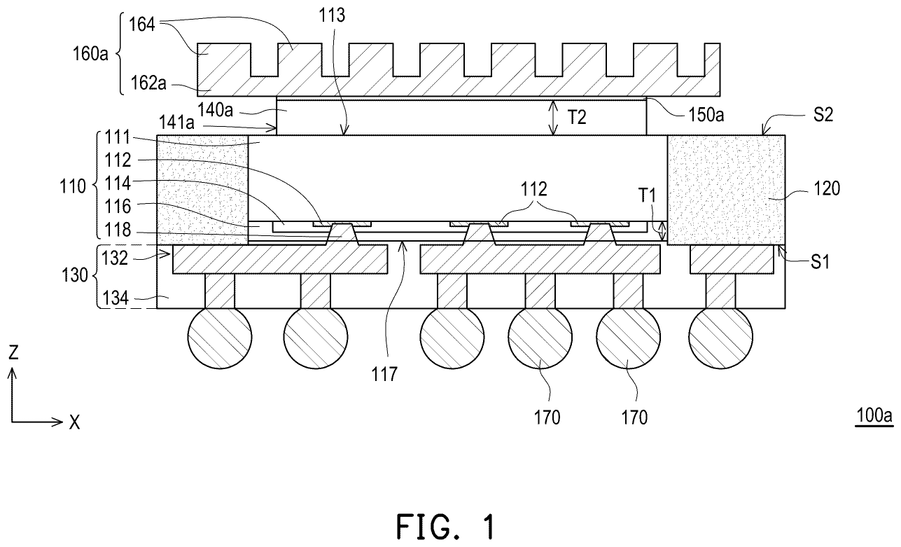

FIG. 1 is a schematic cross-sectional view of a semiconductor device according to an embodiment of the disclosure. Referring to FIG. 1, in this embodiment, a semiconductor device 100a includes an electronic unit 110, an encapsulation layer 120, a circuit structure 130, a protective layer 140a, a first heat conducting element 150a, and a second heat conducting element 160a. The encapsulation layer 120 surrounds the electronic unit 110, and has a first side S1 and a second side S2 opposite to each other. The circuit structure 130 is disposed on the first side S1 of the encapsulation layer 120, and is electrically connected to the electronic unit 110. The protective layer 140a is disposed on the second side S2 of the encapsulation layer 120. The first heat conducting element 150a is disposed on the protective layer 140a. The second heat conducting element 160a is disposed on the first heat conducting element 150a. A thermal conductivity of the second heat conducting element 160a is different from a thermal conductivity of the first heat conducting element 150a. In an embodiment, the thermal conductivity of the second heat conducting element 160a is, for example, between 100 W/mK and 2000 W/mK or between 150 W/mK and 350 W/mK, but the disclosure is not limited thereto. That is to say, the protective layer 140a, the first heat conducting element 150a and the second heat conducting element 160a would be regarded as a composite heat dissipation structure. Because of a design of gradient thermal conductivity between different layer, the heat dissipation of the semiconductor device will be improved.

In an embodiment, the electronic unit 110 may be, for example, a known good die (KGD), a diode, an antenna unit, a sensor, a structure of a semiconductor-related process, or a structure of a semiconductor-related process disposed on a substrate (e.g., polyimide, glass, a silicon substrate, or other suitable substrate materials), but the disclosure is not limited thereto.

Referring to FIG. 1, in this embodiment, the electronic unit 110 may include a semiconductor substrate 111, a pad 112, a passivation layer 114, an insulation layer 116, and a metal pillar 118. In an embodiment, the semiconductor substrate 111 may be, for example, a silicon substrate, which includes an active device and a passive device formed therein, but the disclosure is not limited thereto. The pad 112 is disposed on the semiconductor substrate 111 and may be electrically connected to other conductive elements. A material of the pad 112 may be, for example, aluminum, copper, nickel, molybdenum, titanium, an alloy or a combination of the above materials, or other appropriate metal materials, but the disclosure is not limited thereto. The passivation layer 114 is formed on the semiconductor substrate 111 and has a contact opening exposing a portion of the pad 112. The passivation layer 114 may be, for example, a silicon oxide layer, a silicon nitride layer, a silicon oxynitride layer, or a dielectric layer formed by other appropriate dielectric materials, but the disclosure is not limited thereto. The insulation layer 116 is formed on the passivation layer 114, and a contact opening of the insulation layer 116 partially exposes the pad 112. The insulation layer 116 may be, for example, a polyimide layer or a dielectric layer formed by other appropriate polymers, but the disclosure is not limited thereto. The metal pillar 118 is formed on the pad 112, and the metal pillar 118 may be approximately flush with a surface of the insulation layer 116. A material of the metal pillar 118 may be, for example, copper, but the disclosure is not limited thereto. In an embodiment, a portion of the metal pillar 118 may be embedded in the pad 112. An embedding depth is, for example, 1 micrometer to 10 micrometers, but the disclosure is not limited thereto.

After fabrication of the electronic unit 110 is completed, a singulation cutting process is performed to cut the electronic unit 110 into multiple electronic units 110. Due to the manufacturing process or other factors, sizes of front and back sides of the cut electronic unit 110 may be slightly different. That is, sizes of orthographic projection areas of a backside surface 113 and an active surface 117 of the electronic unit 110 on a plane may be slightly different. In an embodiment, the active surface 117 of the electronic unit 110 may be retracted by a distance in a Z direction relative to the first side S1 of the encapsulation layer 120 due to a high-pressure curing process. That is, the active surface 117 of the electronic unit 110 and the first side S1 of the encapsulation layer 120 are not coplanar. The non-coplanarity means that they are in an X direction. The surface of the encapsulation layer 120 and the active surface 117 are not on the same plane, which allows the electronic unit 110 to reduce crack risk and have better reliability. In an embodiment, the active surface 117 may be, for example, a surface of the electronic unit 110 provided with the metal pillar 118.

Furthermore, the encapsulation layer 120 in this embodiment surrounds the electronic unit 110. In this embodiment, “an element surrounding another element” may mean that the element may be at least partially in contact with a side surface of the another element in a cross-sectional view of the semiconductor device 100a. As shown in FIG. 1, the encapsulation layer 120 may be in direct contact with a side surface of the electronic unit 110. The encapsulation layer 120 may provide the electronic unit 110 with a waterproof effect, thereby improving reliability of the semiconductor device 100a. In an embodiment, a material of the encapsulation layer 120 is, for example, a polymer or an epoxy molding compound (EMC). The encapsulation layer 120 is formed by, for example, a molding process, but the disclosure is not limited thereto. In an embodiment, the backside surface 113 of the electronic unit 110 may be flush with the second side S2 of the encapsulation layer 120, but the disclosure is not limited thereto.

Furthermore, the circuit structure 130 in this embodiment may include any suitable structure formed by stacking a conductive layer 132 and an insulation layer 134. A stacking direction of the insulation layer 134 and the conductive layer 132 may be along the direction Z. In an embodiment, the circuit structure 130 may be in contact with the first side S1 of the encapsulation layer 120. The metal pillar 118 of the electronic unit 110 is in contact with the conductive layer 132 of the circuit structure 130 to be electrically connected to the circuit structure 130. In an embodiment, a material of the conductive layer 132 may be, for example, copper, titanium, nickel, or a combination or an alloy of the above materials, but the disclosure is not limited thereto. In an embodiment, a material of the insulation layer 134 may be, for example, a build up film, polyimide, epoxy, silicon dioxide, silicon nitride, a solder resist, or a combination of the above, but the disclosure is not limited thereto.

In an embodiment, the circuit structure 130 may also be referred to as a redistribution layer. The redistribution layer may be electrically connected to a chip or other electronic elements through a solder ball or other bonding elements. The redistribution layer may include at least one dielectric layer and at least one conductive layer alternately stacked along the direction Z. Through the at least one dielectric layer and the at least one conductive layer, circuits may be redistributed and/or fan-out or fan-in areas of the circuits may be increased, or different electronic elements may be electrically connected to each other through the redistribution layer. For example, a pitch between two adjacent contact pads at an end of the redistribution layer in contact with the electronic element may be less than or equal to a pitch between two adjacent contact pads at an end of the redistribution layer away from the electronic element. Therefore, the redistribution layer may adjust a fan-out condition of the circuit or electrically connect a circuit structure/electronic element with a first pitch to a circuit structure/electronic element with a second pitch, but the disclosure is not limited thereto. A method of forming the redistribution layer may include forming the at least one dielectric layer and the at least one conductive layer by using a photolithography process, a surface processing process, a laser process, an electroplating process, a deposition process, or other processes. The surface processing process includes performing roughness or activation on a surface of the dielectric layer or a surface of the conductive layer to improve an adhesion ability thereof. For example, by increasing surface roughness, an adhesion force with subsequent film layers is improved.

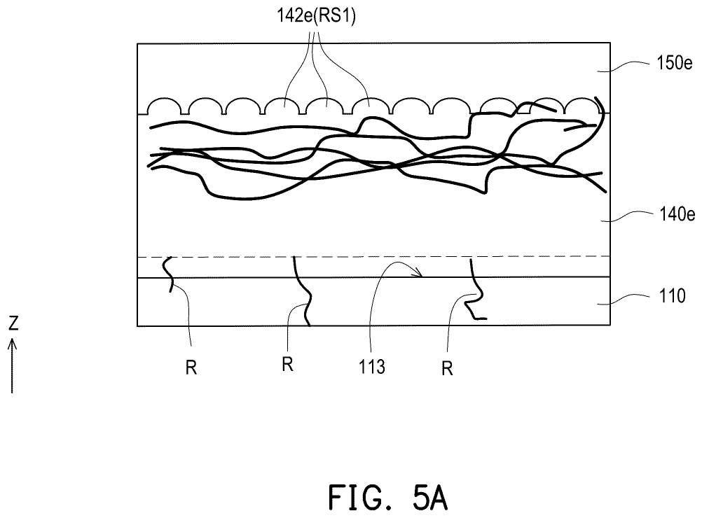

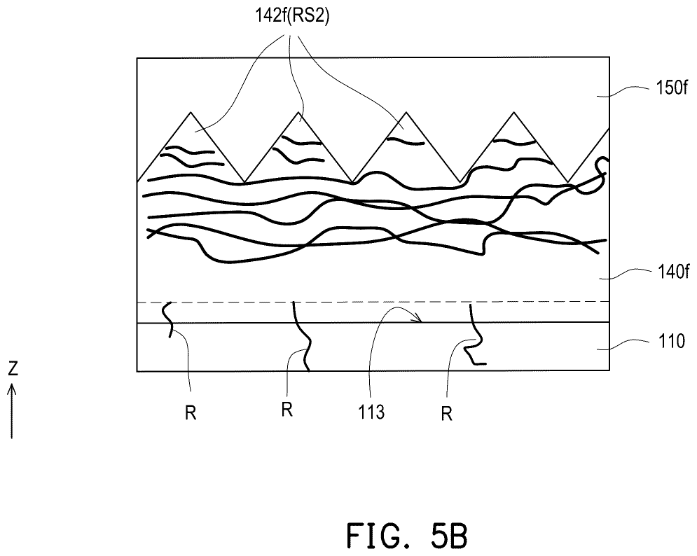

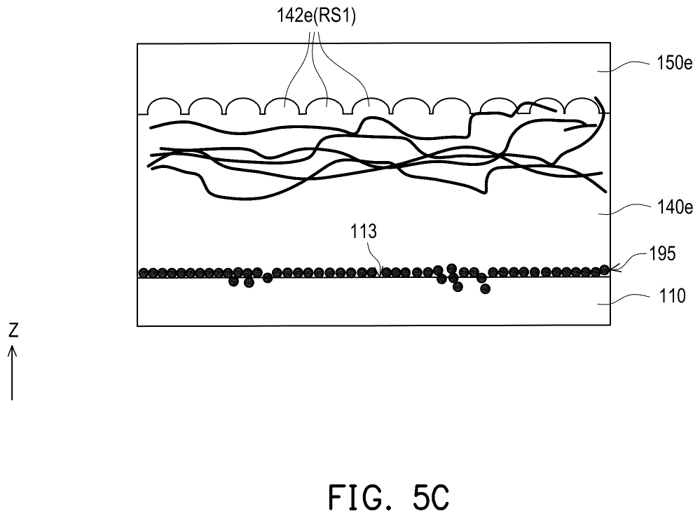

Furthermore, the protective layer 140a in this embodiment is disposed on the second side S2 of the encapsulation layer 120. In detail, the protective layer 140a may be directly located on the backside surface 113 of the electronic unit 110. Since the electronic unit 110 will generate a microstructure R (as shown in FIG. 5A) on the backside surface 113 thereof during a thinning process (e.g., a grinding process, but not limited thereto), and the protective layer 140a is directly disposed on the backside surface 113 of the electronic unit 110 to fill the microstructure R, the microstructure R may be penetrated by the protective layer 140a, thereby increasing an adhesion strength of the protective layer 140a, so as to improve structural reliability of the electronic unit 110. In an embodiment, the protective layer 140a may completely cover the backside surface 113 of the electronic unit 110. That is, a size of the protective layer 140a is greater than or equal to that of the backside surface 113 of the electronic unit 110. In an embodiment, the protective layer 140a may partially cover the backside surface 113 of the electronic unit 110. That is, the size of the protective layer 140a is less than that of the backside surface 113 of the electronic unit 110. In an embodiment, the protective layer 140a is rectangular in a cross-section view, but the disclosure is not limited thereto.

In an embodiment, a material of the protective layer 140a may be, for example, an organic material or an inorganic material. In an embodiment, the material of the protective layer 140a may be, for example, a composite material or a polymer. The composite material may be, for example, metal, metal alloy, silicon carbon, silicon, diamond-like carbon, graphene, cuprocene composite, and thermal conductive silicone, while the polymer may be, for example, polyimide (PI), resin, polyethylene terephthalate (PET), polycarbonate (PC), photoresist (PR), or an Ajinomoto build-up film (ABF). However, the disclosure is not limited thereto. In an embodiment, the Young's modulus of the protective layer 140a is between 55 GPa and 100 GPa. In an embodiment, the Young's modulus of the protective layer 140a is between 70 GPa and 90 GPa. In an embodiment, a coefficient of thermal expansion of the protective layer 140a is, for example, between 2.5 ppm/C and 21 ppm/C. In an embodiment, the coefficient of thermal expansion of the protective layer 140a is, for example, between 5 ppm/C and 15 ppm/C. In an embodiment, the insulation layer 116 of the electronic unit 110 has a first thickness T1, and the protective layer 140a has a second thickness T2. The second thickness T2 is greater than the first thickness T1. In an embodiment, the thickness T2 of the protective layer 140a is, for example, between 0.2 mm and 0.5 mm. In an embodiment, the coefficient of thermal expansion of the protective layer 140a is different from a coefficient of thermal expansion of the insulation layer 116 of the electronic unit 110. In an embodiment, the coefficient of thermal expansion of the protective layer 140a is greater than the coefficient of thermal expansion of the insulation layer 116 of the electronic unit 110. In an embodiment, a material analysis and/or elemental analysis may be performed on the element to know composition of the element by using infrared spectroscopy (IR), energy-dispersive X-ray spectroscopy (EDS), or other suitable methods. Then, a corresponding coefficient of thermal expansion (CTE) of the composition may be obtained by a lookup table, thereby obtaining a coefficient of thermal expansion of the element. The coefficient of thermal expansion of the element affects an expansion and contraction degree of the element, such as deformation. When the coefficient of thermal expansion of the element is greater, the deformation of the element with a temperature is greater, and when the coefficient of thermal expansion of the element is smaller, the deformation of the element with the temperature is smaller.

Referring to FIG. 1 again, in this embodiment, the first heat conducting element 150a is located between the second heat conducting element 160a and the protective layer 140a. In an embodiment, the first heat conducting element 150a is conformally disposed with the protective layer 140a and edges thereof are flush. That is to say, the first heat conducting element 150a exposes a peripheral surface 141a of the protective layer 140a. In an embodiment, the first heat conducting element 150a is, for example, a thermal interface material (TIM), and the second heat conducting element 160a is, for example, an external heat conducting element fixed on the protective layer 140a through the first heat conducting element 150a. In an embodiment, the first heat conducting element 150a is, for example, a seed layer, and the second heat conducting element 160a is formed on the first heat conducting element 150a through processes such as electroplating and lithography, but not limited. In an embodiment, the thermal conductivity of the second heat conducting element 160a may be less than the thermal conductivity of the first heat conducting element 150a. In an embodiment, a material of the second heat conducting element 160a may be copper or aluminum, for example, but the disclosure is not limited thereto.

Furthermore, the second heat conducting element 160a in this embodiment may include a first portion 162a and multiple second portions 164. The first portion 162a is located between the first heat conducting element 150a and the second portions 164, and the second portions 164 are connected to the first portion 162a. In an embodiment, the first portion 162a may extend along the direction X, for example, and the second portions 164 are separated from each other and may extend along the direction Z, for example. In an embodiment, in a cross-section view, a shape of the second portion 164 may be, for example, a square, a rectangle, a trapezoid, a wedge, a cone, a triangle, or a combination of the above shapes, which may increase a heat dissipation surface area.

In addition, the semiconductor device 100a in this embodiment further includes a connecting member 170, which is disposed on the circuit structure 130 and electrically connected to the circuit structure 130. The semiconductor device 100a may be electrically connected to an external circuit through the connecting member 170. In an embodiment, the connecting member 170 may be, for example, tin, nickel, gold, silver, palladium, copper, gallium, an alloy of the above, or a combination thereof, but the disclosure is not limited thereto. In an embodiment, the connecting member 170 is, for example, a solder ball, but the disclosure is not limited thereto.

In this embodiment, the protective layer 140a is located on the second side S2 of the encapsulation layer 120, and the first heat conducting element 150a and the second heat conducting element 160a having different thermal conductivities are sequentially disposed on the protective layer 140a. The protective layer 140a may improve and/or enhance a bursting strength of the electronic unit 110, and the second heat conducting element 160a may enhance heat dissipation performance, so that the semiconductor device 100a in this embodiment may have better structural reliability and heat dissipation effect.

It is noted that some of the reference numerals and descriptions of the above embodiment will apply to the following embodiments. The same reference numerals will represent the same or similar components and the descriptions of the same technical contents will be omitted. Reference may be made to the above embodiment for the omitted descriptions, which will not be repeated in the following embodiments.

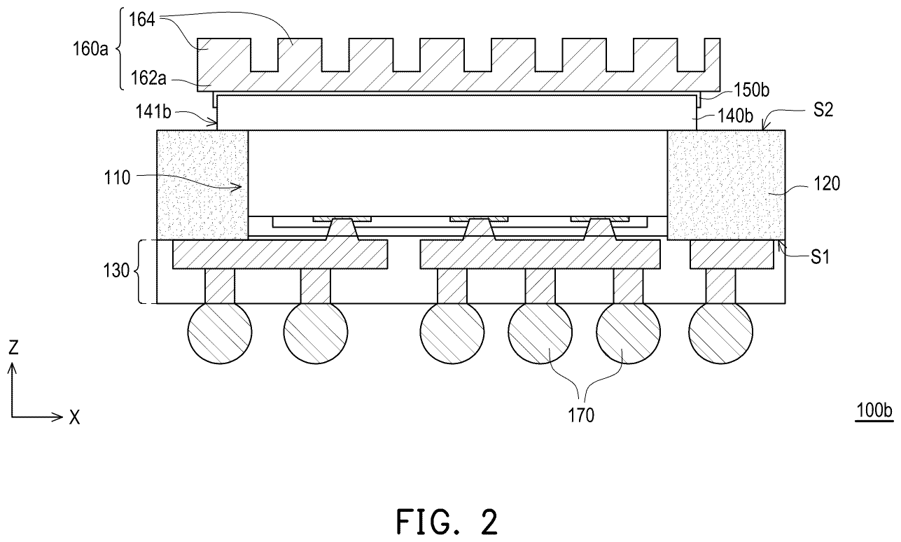

FIG. 2 is a schematic cross-sectional view of a semiconductor device according to another embodiment of the disclosure. Referring to both FIG. 1 and FIG. 2, a semiconductor device 100b in this embodiment is similar to the semiconductor device 100a in FIG. 1. A difference between the two is that in this embodiment, a protective layer 140b further extends to cover the second side S2 of the encapsulation layer 120, and a first heat conducting element 150b extends to cover a portion of a peripheral surface 141b of the protective layer 140b.

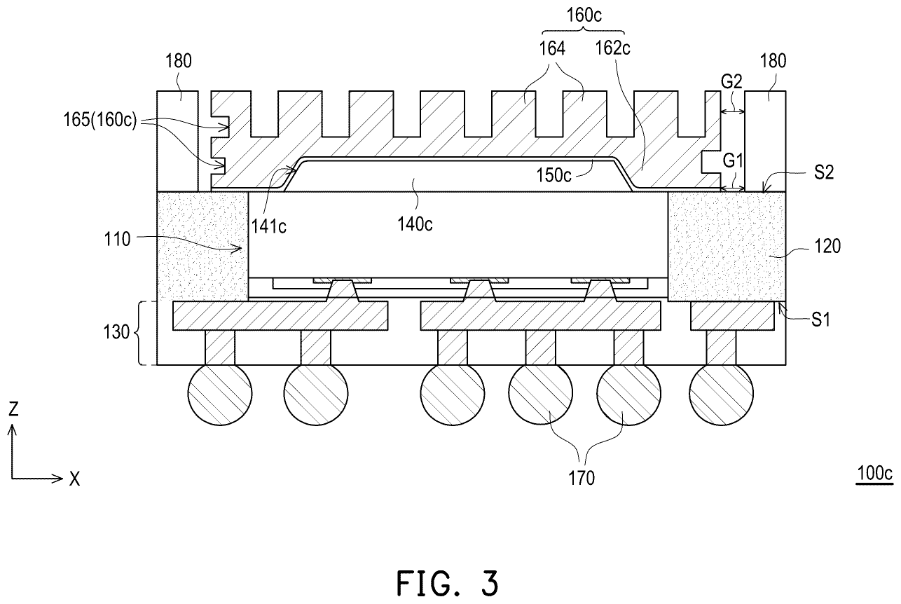

FIG. 3 is a schematic cross-sectional view of a semiconductor device according to another embodiment of the disclosure. Referring to both FIG. 1 and FIG. 3, a semiconductor device 100c in this embodiment is similar to the semiconductor device 100a in FIG. 1. A difference between the two is that in this embodiment, a shape of a protective layer 140c is a trapezoid in a cross-section view, and a first heat conducting element 150c conformally completely covers a peripheral surface 141c of the protective layer 140c and extends to the second side S2 of the encapsulation layer 120. A portion of a first portion 162c of a second heat conducting element 160c is also thickened and extends to an edge of the first heat conducting element 150c. In an embodiment, the second heat conducting element 160c may include at least one third portion 165, wherein along the X direction, the first portion 162c is disposed between two third portion 165, which may increase a heat dissipation area. In an embodiment, an edge of the second heat conducting element 160c may be aligned with the edge of the first heat conducting element 150c. In addition, the semiconductor device 100c in this embodiment further includes a barrier layer 180 disposed on the second side of the encapsulation layer. The barrier layer 180 can be continuous or discontinuous in a top view direction (Z direction). In a cross section view (X direction, the first heat conducting element 150c and the second heat conducting element 160c are disposed between two part of the barrier layer 180. In an embodiment, along the direction X, a first distance G1 between the barrier layer 180 and the first heat conducting element 150c is less than or equal to a second distance G2 between the barrier layer 180 and the second heat conducting element 160c. In other words, the barrier layer 180 is not in contact with the protective layer 140c, the first heat conducting element 150c and the second heat conducting element 160c. In an embodiment, the barrier layers 180 is in contact with at least one of the protective layer 140c, the first heat conducting element 150c or the second heat conducting element 160c.

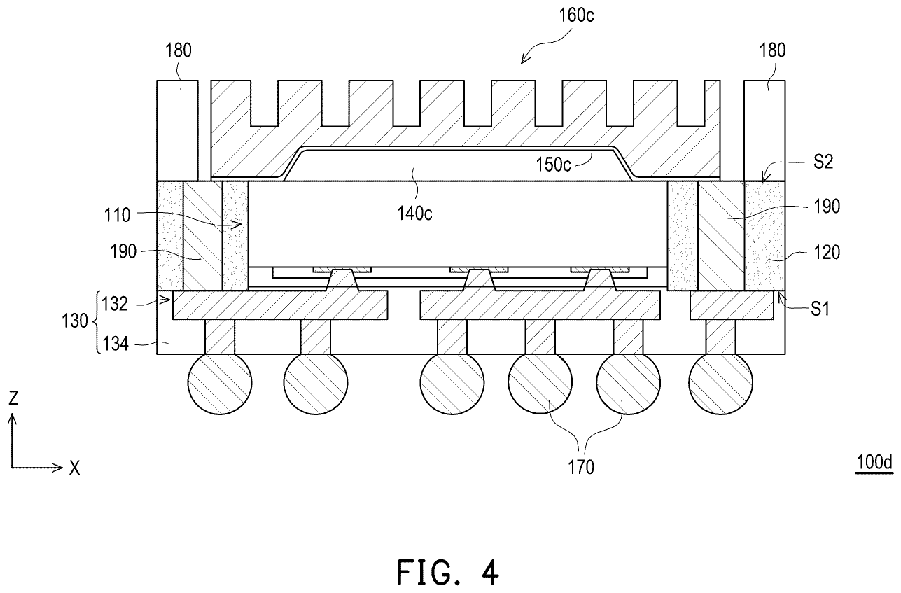

FIG. 4 is a schematic cross-sectional view of a semiconductor device according to another embodiment of the disclosure. Referring to both FIG. 3 and FIG. 4, a semiconductor device 100d in this embodiment is similar to the semiconductor device 100c in FIG. 3. A difference between the two is that in this embodiment, the semiconductor device 100d further includes a third heat conducting element 190 that penetrates through the encapsulation layer 120 and is connected to a portion of the first heat conducting element 150c and the conductive layer 132 of the circuit structure 130. In an embodiment, the third heat conducting element 190 may have functions of electrical conduction, heat conduction, or both electrical conduction and heat conduction.

FIG. 5A to FIG. 5C are schematic partial cross-sectional enlarged views of multiple semiconductor devices according to multiple embodiments of the disclosure. Referring to FIG. 5A, in this embodiment, a microstructure R is generated on the backside surface 113 of the electronic unit 110 by grinding, and a protective layer 140e is directly disposed on the backside surface 113 of the electronic unit 110 and penetrates into the microstructure R to increase an adhesion strength of the protective layer 140e, which may improve the structural reliability. Furthermore, compared to the protective layer 140a in FIG. 1, the protective layer 140e in this embodiment further has a rough surface RS1 away from the microstructure R of the electronic unit 110. The rough surface RS1 is formed by multiple concave-convex structures 142e. In a cross-sectional view, the concave-convex structures 142e may be, for example, semicircular or semi-elliptical. The protective layer 140e having the concave-convex structures 142e may increase the heat dissipation area, which may enhance an effect of heat conduction. In an embodiment, surface roughness of the backside surface 113 of the electronic unit 110 may be less than roughness of the rough surface RS1 of the protective layer 140e.

Next, referring both to FIG. 5A and FIG. 5B, this embodiment is similar to the above embodiment. A difference between the two is that in this embodiment, a protective layer 140f in this embodiment further has a rough surface RS2. The rough surface RS2 is formed by multiple concave-convex structures 142f. In a cross-sectional view, the concave-convex structures 142f may be, for example, triangular or zigzag-shaped. The protective layer 140f having the concave-convex structures 142f may increase the heat dissipation area, which may the effect of heat conduction. In an embodiment, the surface roughness of the backside surface 113 of the electronic unit 110 may be less than roughness of the rough surface RS2 of the protective layer 140f.

Next, referring to both FIG. 5A and FIG. 5C, this embodiment is similar to the above embodiment. A difference between the two is that in this embodiment, a conductor layer 195 is further included between the electronic unit 110 and the protective layer 140e. The conductor layer 195 is disposed on the backside surface 113 of the electronic unit 110 to cover the microstructure R on the backside surface 113 of the electronic unit 110.

In an embodiment, the protective layer may be a single-layer structure or a multi-layer structure. In an embodiment, the protective layer is a multi-layer structure, which is formed by stacking multiple films along the direction Z. In an embodiment, the protective layer may have a flat surface. In an embodiment, the protective layer may have a rough surface, and the rough surface may be formed by the microstructure. In short, the protective layer in this embodiment may improve and/or enhance the bursting strength of the electronic unit 110 and may enhance the heat dissipation effect by forming the microstructure.

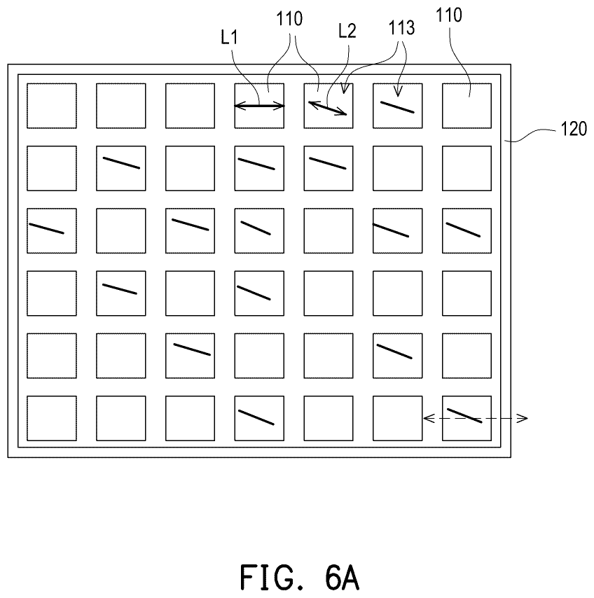

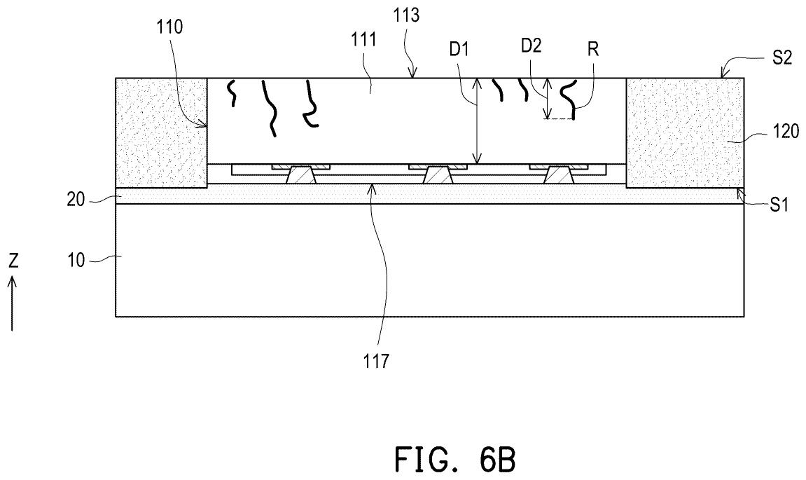

In this embodiment, after the grinding process of the panel-level package, in order to measure the microstructure R of the electronic unit 110, the protective layer disposed on the backside surface 113 of the electronic unit 110 is first removed, and then the microstructure R is measured. FIG. 6A is a schematic top view of a semiconductor device according to an embodiment of the disclosure. FIG. 6B is a schematic partial cross-sectional view of the semiconductor device in FIG. 6A. In some embodiments, a complete area of a wafer is provided. In some embodiments, a partial area of the wafer is provided.

Referring to both FIG. 6A and FIG. 6B, in this embodiment, the electronic unit 110 with the protective layer removed and the encapsulation layer 120 surrounding the electronic unit 110 are disposed on a carrier 10 and fixed on the carrier 10 through an adhesive layer 20 on the carrier 10. At this time, the backside surface 113 of the electronic unit 110 and the second side S2 of the encapsulation layer 120 are exposed to the outside, and the active surface 117 of the electronic unit 110 and the first side S1 of the encapsulation layer are attached to the adhesive layer 20. In an embodiment, the carrier 10 may be, for example, a glass substrate, a printed circuit board, a fiberglass (FR4) substrate, a steel substrate, or other suitable substrates, and the disclosure is not limited thereto. In an embodiment, the adhesive layer 20 may include, for example, an ultraviolet (UV) release tape, a heat release tape (HRT), other suitable materials, or a combination of any two of the above. By disposing the adhesive layer 20 on the carrier 10, the carrier 10 may be effectively separated from the electronic unit 110 subsequently.

Next, features of the microstructure R of the backside surface 113 of the electronic unit 110 are measured through a microscope. Referring to FIG. 6A, in a top view, the electronic unit 110 has an element length L1 and a microstructure length L2. The microstructure length L2 is less than ½ or ⅓ of the element length L1. Here, the element length L1 refers to the longest length of the electronic unit 110 in a top-view direction. In some embodiments, the element length L1 may be, for example, a straight-line distance between two opposite sides of the electronic unit 110. In another embodiment, the element length L1 may be, for example, a straight-line distance between two vertices of the electronic unit 110. The microstructure length L2 refers to the longest scratch in one single element length 110. That is, a connection distance between two end points is taken. Referring to FIG. 6B, in a cross-sectional view, the electronic unit 110 has an element depth D1 and a microstructure depth D2, and the microstructure depth D2 is less than ½ or ⅓ of the element depth D1. In an embodiment, the element depth D1 may be, for example, a length of the electronic unit 110 in a normal direction. In some other embodiments, the element depth D1 may refer to a length of the semiconductor substrate 111 in the normal direction. The microstructure depth D2 refers to the longest deep scratch in one single electronic unit 110. For example, the connection distance between the two end points in the normal direction of the electronic unit 110 is taken. The microstructure depth D2 may be, for example, less than or equal to 1 micrometer, but the disclosure is not limited thereto.

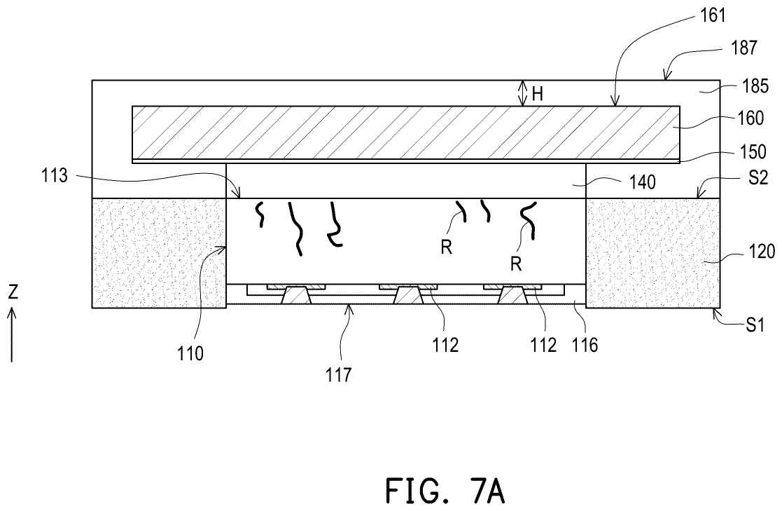

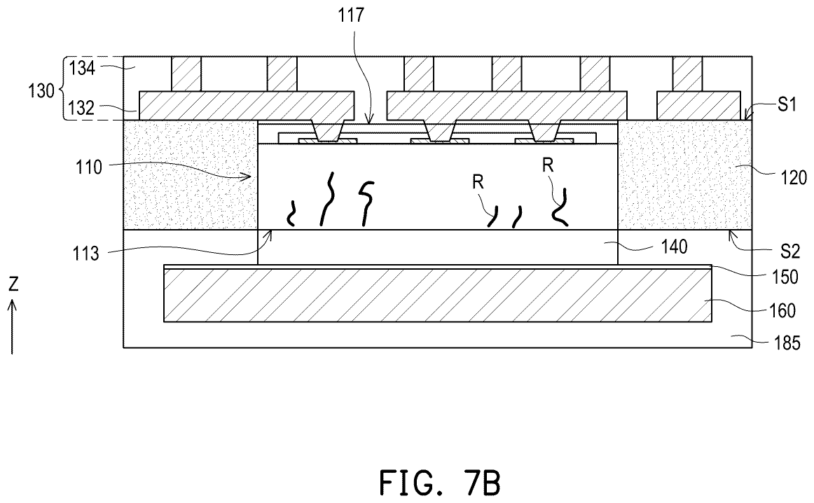

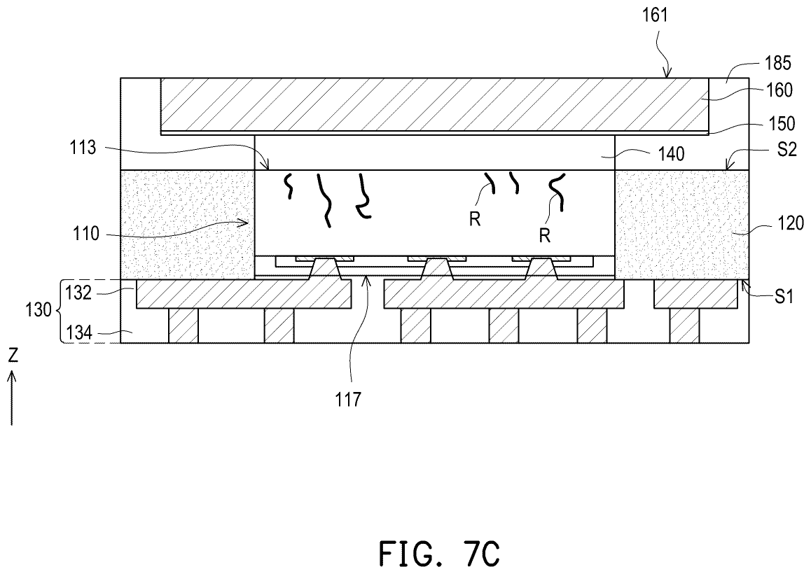

FIG. 7A to FIG. 7C are schematic cross-sectional views of a manufacturing method of a semiconductor device according to an embodiment of the disclosure. Referring to FIG. 7A, regarding the manufacturing method of the semiconductor device in this embodiment, first, the electronic unit 110 is disposed on a temporary carrier (not shown) through a temporary adhesive layer (not shown). Next, the encapsulation layer 120 is formed on the electronic unit 110. The encapsulation layer 120 surrounds the electronic unit 110 to form a package structure. Next, another temporary carrier (not shown) is provided, and the temporary adhesive layer and the temporary carrier are removed. The package structure may be temporarily fixed on the another temporary carrier, so that the backside surface 113 of the electronic unit 110 is away from the temporary carrier. In the method described above, if the electronic unit 110 is packaged on the temporary substrate in a manner that the active surface 117 is initially away from the temporary substrate, it may be referred to as a chip face-up process. According to some embodiments, the electronic unit 110 may also be packaged on the temporary carrier in a manner that the active surface 117 faces the temporary carrier, and then the backside surface 113 of the electronic unit 110 is exposed, which may be referred to as a chip face-down process.

In an embodiment, the temporary carrier may be, for example, a glass substrate, a printed circuit board, a fiberglass (FR4) substrate, a steel substrate, or other suitable substrates, and the disclosure is not limited thereto. In an embodiment, the encapsulation layer 120 may be, for example, a molding compound, an epoxy resin, other suitable package materials, or a combination of the above, and the disclosure is not limited thereto. According to some embodiments, a dissociation method of the adhesive layer may include photodissociation, thermal dissociation, other suitable methods, or a combination of any two of the above methods. For example, depending on the dissociation method, the adhesive layer may be used with different types of temporary carriers. For example, a photodissociation type adhesive layer may be used with a transparent glass substrate, while a thermal-dissociation type adhesive layer may be used with a steel plate. The adhesive layer may include, for example, an ultraviolet (UV) release tape, a heat release tape (HRT), other suitable materials, or a combination of any two of the above. By disposing the adhesive layer on the temporary carrier, the package structure may be effectively separated.

According to some embodiments, when the chip face-down process is adopted, after the package structure is formed through the molding process, and the package structure is flipped over, an opening of the insulation layer 116 of the electronic unit 110 may expose the pad 112. When the chip face-up process is adopted, and the encapsulation layer 120 overlaps the pad 112, or the encapsulation layer 120 and the insulation layer 116 overlap the pad 112 at the same time, subsequently, a patterning process is required to expose the pad 112 to facilitate the subsequent processes. Patterning steps may include photolithography, etching, development, laser, plasma cleaning, a combination of the above, or other suitable steps, and the disclosure is not limited thereto.

Next, referring to FIG. 7A again, the encapsulation layer 120 is ground until the backside surface 113 of the electronic unit 110 is exposed to form the encapsulation layer 120 having the first side S1 and the second side S2 opposite to each other. After grinding, the microstructures R are formed on the backside surface 113 of the electronic unit 110. In an embodiment, a depth of the microstructure R may be, for example, less than or equal to 1 micrometer, but the disclosure is not limited thereto.

Next, referring to FIG. 7A again, the protective layer 140 is formed on the second side S2 of the encapsulation layer 120. In an embodiment, the protective layer 140 has a flat surface relatively away from the second side S2 of the encapsulation layer 120. In an embodiment, the protective layer 140 may have the unevenness structure, such as the concave-convex structures 142e in FIG. 5A or the concave-convex structures 142f in FIG. 5B, but the disclosure is not limited thereto. In an embodiment, methods of forming the protective layer 140 include adopting taping, injection molding, slit coating, spin coating, spinless coating, electroplating, chemical plating, deposition (CVD, PVD, ALD, MOCVD, MPCVD), lamination, or dipping, or using a laser beam, microwave, or plasma, but the disclosure is not limited thereto. In an embodiment, the material of the protective layer 140 may be, for example, the organic material or the inorganic material. In an embodiment, the material of the protective layer 140 may be, for example, the composite material or the polymer. The composite material may be, for example, diamond-like carbon, graphene, cuprocene composite, and thermal conductive silicone, while the polymer may be, for example, polyimide (PI), resin, polyethylene terephthalate (PET), polycarbonate (PC), photoresist (PR), or the Ajinomoto build-up film (ABF). However, the disclosure is not limited thereto.

Next, referring to FIG. 7A again, the first heat conducting element 150 is formed on the protective layer 140. In an embodiment, a size of the first heat conducting element 150 may be greater than or equal to the size of the protective layer 140. Next, the second heat conducting element 160 is formed on the first heat conducting element 150. The thermal conductivity of the second heat conducting element 160 is different from the thermal conductivity of the first heat conducting element 150. In one embodiment, the thermal conductivity of the second heat conducting element 160 is different from the thermal conductivity of the first heat conducting element 150.

In an embodiment, the first heat conducting element 150 may be, for example, a seed material layer as a metal layer, which may be a single layer, or a composite layer of multiple sub-layers formed by different materials. In an embodiment, the seed material layer may include a titanium layer and a copper layer above the titanium layer. The seed material layer may be formed by using, for example, PVD or a similar method. Next, a patterned photoresist layer is formed on the seed material layer. The patterned photoresist layer exposes a portion of the seed material layer. Next, the patterned photoresist layer is used as an electroplating mask to electroplate a metal material on the seed material layer exposed by the patterned photoresist layer. Next, the patterned photoresist layer and the seed material layer thereunder are removed to form the second heat conducting element 160 and the first heat conducting element 150 thereunder. It should be noted that the second heat conducting element 160 is provided through electroplating, but the disclosure is not limited thereto. In other embodiments, the first heat conducting element 150 may also be, for example, a thermal interface material (TIM), and the second heat conducting element 160 is fixed on the protective layer 140 through the first heat conducting element 150. That is to say, the second heat conducting element 160 is an external heat conducting element.

Next, a buffer layer 185 is formed on the second side S2 of the encapsulation layer 120. The buffer layer 185 covers the protective layer 140, the first heat conducting element 150, and the second heat conducting element 160. At this time, a top surface 187 of the buffer layer 185 and a top surface 161 of the second heat conducting element 160 have a height difference H. The top surface 187 of the buffer layer 185 is higher than the top surface 161 of the second heat conducting element 160. In an embodiment, a material of the buffer layer 185 is, for example, an organic material or an inorganic material, but the disclosure is not limited thereto.

Next, referring to both FIG. 7A and FIG. 7B, a structure in FIG. 7A is flipped over, so that the first side S1 of the encapsulation layer 120 faces upward. Next, the circuit structure 130 is formed on the first side S1 of the encapsulation layer 120. The circuit structure 130 is electrically connected to the electronic unit 110.

Afterwards, referring to both FIG. 7B and FIG. 7C, a structure in FIG. 7B is flipped over, so that the second side S2 of the encapsulation layer 120 faces upward. Next, the buffer layer 185 is thinned to expose the top surface 161 of the second heat conducting element 160. Finally, according to use requirements, the second heat conducting element 160 may be patterned to form a fin state, and the connecting member may be selectively formed on the circuit structure 130 to be electrically connected to the external circuit, thereby completing fabrication of the semiconductor device.

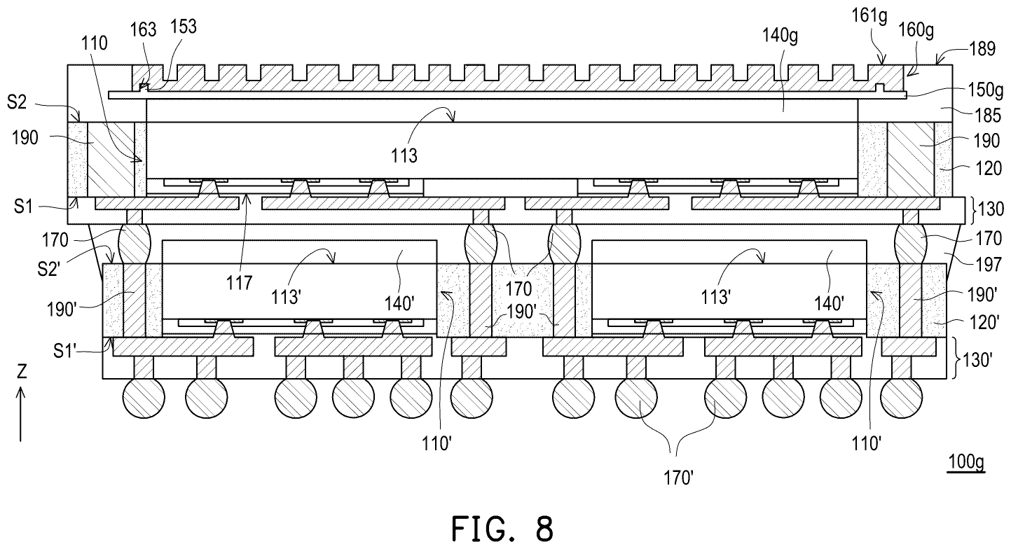

FIG. 8 is a schematic cross-sectional view of a semiconductor device according to another embodiment of the disclosure. Referring to both FIG. 1 and FIG. 8, a semiconductor device 100g in this embodiment is similar to the semiconductor device 100a in FIG. 1. A difference between the two is that in this embodiment, the semiconductor device 100g further includes the third heat conducting element 190 disposed adjacent to the electronic unit 110, and the encapsulation layer 120 surrounds the third heat conducting element 190. In this embodiment, the third heat conducting element 190 surrounds the electronic unit 110, and the encapsulation layer 120 covers peripheral surfaces of the electronic unit 110 and the third heat conducting element 190. One end of the third heat conducting element 190 is in direct contact with the circuit structure 130, and another end of the third heat conducting element 190 extends to the second side S2 of the encapsulation layer 120. That is to say, heat generated by the electronic unit 110 may not only be directly transferred to the outside through a first heat conducting element 150g and a second heat conducting element 160g disposed on the backside surface 113, but may also be transferred to the outside through the circuit structure 130 disposed on the active surface 117 thereof via the third heat conducting element 190, which may enhance the heat dissipation effect and enable the electronic device 100g to have better heat dissipation efficiency.

Furthermore, in this embodiment, a size of a protective layer 140g may be slightly greater than a size of the backside surface 113 of the electronic unit 110. The first heat conducting element 150g located on the protective layer 140g may have a first limiting portion 153, and the second heat conducting element 160g may have a second limiting portion 163. The first limiting portion 153 and the second limiting portion 163 cooperate with each other to fix the second heat conducting element 160g on the first heat conducting element 150g. In an embodiment, one of the first limiting portion 153 and the second limiting portion 163 is a groove, and the other of the first limiting portion 153 and the second limiting portion 163 is a bump. In an embodiment, the first limiting portion 153 is a bump, and the second limiting portion 163 is a groove. In addition, the semiconductor device 100g in this embodiment further includes the buffer layer 185, which is disposed on the second side S2 of the encapsulation layer 120. The buffer layer 185 surrounds the protective layer 140, the first heat conducting element 150g, and the second heat conducting element 160g. At this time, a top surface 189 of the buffer layer 185 is flush with a top surface 161g of the second heat conducting element 160g, but the disclosure is not limited thereto.

Referring to FIG. 8 again, in this embodiment, the semiconductor device 100g further includes an electronic unit 110′, a encapsulation layer 120′, a circuit structure 130′, a protective layer 140′, a connecting member 170′, and a third heat conducting element 190′. The encapsulation layer 120′ surrounds the electronic unit 110, and has a first side S1′ and a second side S2′ opposite to each other. The circuit structure 130′ is disposed on the first side S1′ of the encapsulation layer 120′, and is electrically connected to the electronic unit 110′. The protective layer 140′ is disposed on the second side S2′ of the encapsulation layer 120′ and directly covers a backside surface 113′ of the electronic unit 110′. The third heat conducting element 190′ is disposed adjacent to the electronic unit 110′, and the encapsulation layer 120′ surrounds the third heat conducting element 190′. The third heat conducting element 190′ surrounds the electronic unit 110′, and the encapsulation layer 120′ covers peripheral surfaces of the electronic unit 110′ and the third heat conducting element 190′. One end of the third heat conducting element 190′ is in direct contact with the circuit structure 130′, and another end of the third heat conducting element 190′ is exposed outside the second side S2′ of the encapsulation layer 120′. The connecting member 170 is directly connected to the another end of the third heat conducting element 190′. The connecting member 170′ is connected to the circuit structure 130′, so that the semiconductor device 100g may be electrically connected to the external circuit through the connecting member 170′. In addition, the semiconductor device 100g in this embodiment further includes an underfill 197 disposed between the circuit structure 130 and the encapsulation layer 120′, and at least covers the connecting member 170, so as to protect the connecting member 170 and ensure electrical connection between the electronic unit 110 and the electronic unit 110′. In short, the semiconductor device 100g in this embodiment is formed by the electronic unit 110 and the electronic unit 110′ vertically stacked in the direction Z.

Based on the above, in the embodiment of the disclosure, the protective layer is located on the second side of the encapsulation layer, and the first heat conducting element and the second heat conducting element having different thermal conductivities are sequentially disposed on the protective layer. The protective layer may improve and/or enhance the bursting strength of the electronic unit, and the heat conducting element may enable the semiconductor device in the disclosure to have the better heat dissipation effect.

Finally, it should be noted that the above embodiments are only used to illustrate but not to limit the technical solutions of the disclosure. Although the disclosure has been described in detail with reference to the foregoing embodiments, persons skilled in the art should understand that they may still modify the technical solutions described in the foregoing embodiments or equivalently replace some or all of the technical features. However, the modifications or replacements do not cause the spirit of the corresponding technical solution to deviate from the scope of the technical solution according to each embodiment of the disclosure.

What is claimed is:

1. A semiconductor device, comprising:
an electronic unit;
an encapsulation layer surrounding the electronic unit and having a first side and a second side opposite to each other;
a circuit structure disposed on the first side of the encapsulation layer and electrically connected to the electronic unit;
a protective layer disposed on the second side of the encapsulation layer;
a first heat conducting element disposed on the protective layer; and
a second heat conducting element disposed on the first heat conducting element, wherein a thermal conductivity of the second heat conducting element is different from a thermal conductivity of the first heat conducting element.

2. The semiconductor device according to claim 1, wherein the thermal conductivity of the second heat conducting element is less than the thermal conductivity of the first heat conducting element.

3. The semiconductor device according to claim 1, wherein the thermal conductivity of the second heat conducting element is between 100 W/mK and 2000 W/mK or between 150 W/mK and 350 W/mK.

4. The semiconductor device according to claim 1, further comprising:
a barrier layer disposed on the second side of the encapsulation layer, wherein the first heat conducting element and the second heat conducting element are disposed between two part of the barrier layer.

5. The semiconductor device according to claim 4, wherein along a direction perpendicular to a normal direction of the electronic unit, a first distance between the barrier layer and the first heat conducting element is less than or equal to a second distance between the barrier layer and the second heat conducting element.

6. The semiconductor device according to claim 1, wherein in a top view, the electronic unit has an element length and a microstructure length, and the microstructure length is less than ½ of the element length.

7. The semiconductor device according to claim 1, wherein in a cross-sectional view, the electronic unit has an element depth and a microstructure depth, and the microstructure depth is less than ½ of the element depth.

8. The semiconductor device according to claim 1, wherein the electronic unit comprises an insulation layer having a first thickness, and the protective layer has a second thickness, wherein the second thickness is greater than the first thickness.

9. The semiconductor device according to claim 1, wherein the protective layer has a rough surface away from electronic unit, and the rough surface comprises a plurality of concave-convex structures.

10. The semiconductor device according to claim 1, wherein an active surface of the electronic unit is not coplanar with the first side of the encapsulation layer.

11. The semiconductor device according to claim 1, wherein a backside surface of the electronic unit is flush with the second side of the encapsulation layer.

12. The semiconductor device according to claim 1, wherein the circuit structure comprises a conductive layer and an insulation layer that are stacked.

13. The semiconductor device according to claim 1, wherein the protective layer completely covers or partially covers a backside surface of the electronic unit.

14. The semiconductor device according to claim 1, wherein a material of the protective layer comprises an organic material or an inorganic material.

15. The semiconductor device according to claim 1, wherein the second heat conducting element comprises a first portion and a plurality of second portions, and the first portion is located between the first heat conducting element and the plurality of second portions.

16. The semiconductor device according to claim 1, further comprising:
a connecting member disposed on the circuit structure and electrically connected to the circuit structure.

17. The semiconductor device according to claim 1, wherein the second heat conducting element comprises at least one third portion.

18. The semiconductor device according to claim 1, further comprising:
a third heat conducting element penetrating through the encapsulation layer and connected to a portion of the first heat conducting element and the circuit structure.

19. A manufacturing method of a semiconductor device, comprising:
forming a encapsulation layer on an electronic unit, wherein the encapsulation layer surrounds the electronic unit;
grinding the encapsulation layer until a backside surface of the electronic unit is exposed;
forming a circuit structure on a first side of the encapsulation layer, wherein the circuit structure is electrically connected to the electronic unit;
forming a protective layer on a second side of the encapsulation layer;
forming a first heat conducting element on the protective layer; and
forming a second heat conducting element on the first heat conducting element, wherein a thermal conductivity of the second heat conducting element is different from a thermal conductivity of the first heat conducting element.

20. The manufacturing method of the semiconductor device according to claim 19, wherein a material of the protective layer comprises a composite material or a polymer.
